(19) United States
(12) Patent Application Publication
(10) Pub. No.: US 2026/0239710 A1
(43) Pub. Date: Aug. 13, 2026

(54) BACKSIDE CONTACT WITH PARTIAL SIDEWALL SPACER

(71) Applicant: INTERNATIONAL BUSINESS MACHINES CORPORATION, Armonk, NY (US)

(72) Inventors: Xiaoming Yang, Clifton Park, NY (US); Ruilong Xie, Niskayuna, NY (US); Ravikumar Ramachandran, Pleasantville, NY (US); Reinaldo Vega, Mahopac, NY (US); Kisik Choi, Watervliet, NY (US); Nicolas Jean Loubet, GUILDERLAND, NY (US)

(21) Appl. No.: 19/048,031

(22) Filed: Feb. 7, 2025

(51) Int. Cl. H10D 64/23; H10D 30/00; H10D 62/10; H10D 64/01; H10D 64/62

(52) U.S. Cl. CPC H10D 64/258; H10D 30/501; H10D 62/115; H10D 64/01; H10D 64/62

(57) ABSTRACT

A nanosheet semiconductor structure including a backside contact structure, top semiconductor layer adjacent to, and in electrical contact with, a bottom portion of the backside contact structure, and sidewall spacers between and physically separating a top portion of the backside contact structure from the top semiconductor layer.

### BACKGROUND

The present invention generally relates to semiconductor structures, and more particularly to nanosheet transistor structures having a backside contact with a partial sidewall spacer.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a backside contact structure, top semiconductor layer adjacent to, and in electrical contact with, a bottom portion of the backside contact structure, and sidewall spacers between and physically separating a top portion of the backside contact structure from the top semiconductor layer.

According to another embodiment of the present invention, a semiconductor structure is provided. The semiconductor structure may include a backside contact structure, top semiconductor layer adjacent to, and in electrical contact with, a bottom portion of the backside contact structure, sidewall spacers between and physically separating a top portion of the backside contact structure from the top semiconductor layer, and a first silicide region arranged at a top of the backside contact structure.

According to another embodiment of the present invention, a semiconductor structure is provided. The semiconductor structure may include a backside contact structure, a top semiconductor layer adjacent to, and in electrical contact with, a bottom portion of the backside contact structure, sidewall spacers between and physically separating a top portion of the backside contact structure from the top semiconductor layer, a first silicide region between and direct contacting the backside contact structure and a source drain region, and a second silicide region between and direct contacting the backside contact structure the top semiconductor layer.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2 and 3 are cross-sectional views of the semiconductor structure during an intermediate step of a method of fabricating nanosheet transistor structures according to an exemplary embodiment;

FIGS. 4 and 5 are cross-sectional views of the semiconductor structure after flipping the assembly and recessing the substrate according to an exemplary embodiment;

FIGS. 6 and 7 are cross-sectional views of the semiconductor structure after removing and recessing remaining portions of the substrate according to an exemplary embodiment;

FIGS. 8 and 9 are cross-sectional views of the semiconductor structure after forming backside dielectric layer according to an exemplary embodiment;

FIGS. 10 and 11 are cross-sectional views of the semiconductor structure after forming backside contact trenches according to an exemplary embodiment;

FIGS. 12 and 13 are cross-sectional views of the semiconductor structure after forming a dielectric liner according to an exemplary embodiment;

FIGS. 14 and 15 are cross-sectional views of the semiconductor structure after forming a mask according to an exemplary embodiment;

FIGS. 16 and 17 are cross-sectional views of the semiconductor structure after removing portions of the dielectric liner according to an exemplary embodiment;

FIGS. 18 and 19 are cross-sectional views of the semiconductor structure after removing additional portions of the dielectric liner according to an exemplary embodiment; and

FIGS. 20 and 21 are cross-sectional views of the semiconductor structure after forming backside contact structures and backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating device contacts on a backside of the wafer presents unique challenges. More specifically, for example, conventional backside contact and placeholder fabrication techniques result in reduced backside contact size due to placeholder trimming during substrate removal. Additionally, tighter pitch and reduced feature further reduce actual distance between a backside contact and the gate structure. Relatively small distances between a backside contact and the gate structure increases the possibility of silicon diffusion in the inner spacer causing shorts between the gate structure and the backside contact.

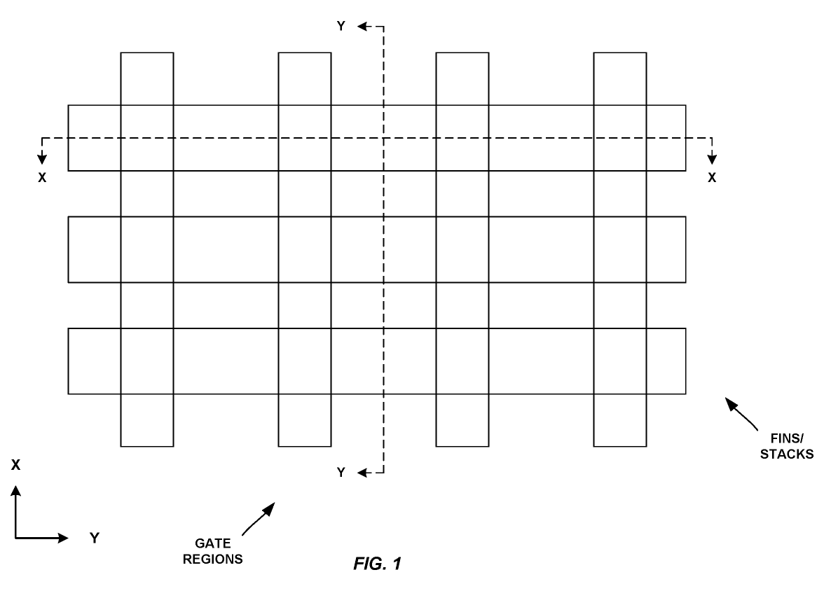

The present invention generally relates to semiconductor structures, and more particularly to nanosheet transistor structures having a backside contact with a sidewall spacer. More specifically, the nanosheet transistor structures and associated method disclosed herein enable a novel solution for providing nanosheet transistor structures having a backside contact with a partial sidewall spacer enabling direct contact between the backside contact and the substrate on the backside. Exemplary embodiments of nanosheet transistor structures having a backside contact with a partial sidewall spacer are described in detail below by referring to the accompanying drawings in FIGS. 1 to 21. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms "vertical" or "vertical direction" or "vertical height" as used herein denote a Z-direction of the Cartesian coordinates shown in the drawings, and the terms "horizontal," or "horizontal direction," or "lateral direction" as used herein denote an X-direction and/or a Y-direction of the Cartesian coordinates shown in the drawings.

The generic structure illustrated in FIG. 1 shows multiple fins/stacks and multiple gate regions situated perpendicular to one another. FIGS. 1-21 represent cross section views oriented as indicated in FIG. 1

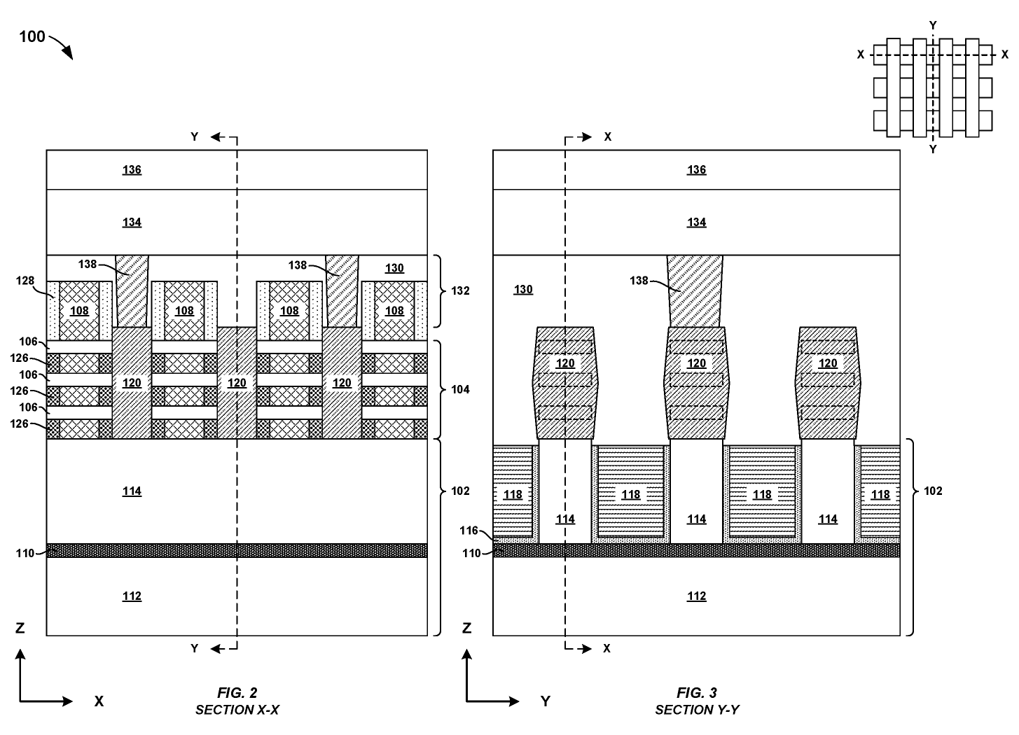

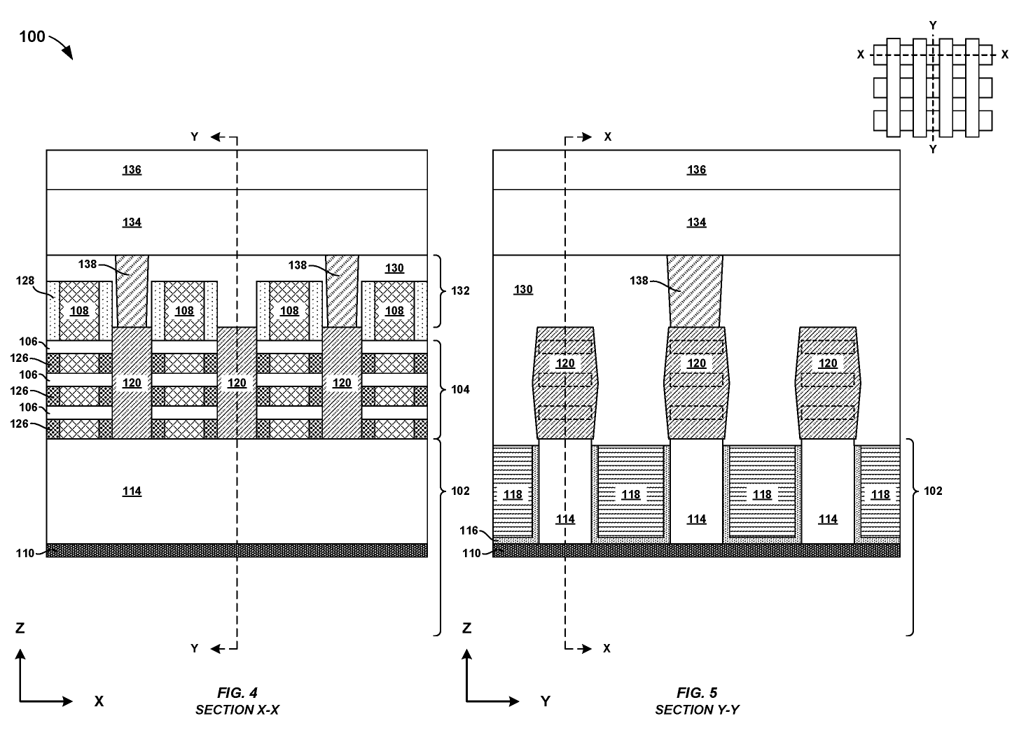

Referring now to FIGS. 2 and 3, a structure 100 is shown during an intermediate step of a method of fabricating a nanosheet transistor structure according to an embodiment of the invention. FIG. 2 depicts a cross-sectional view of the structure 100 shown in FIG. 3 taken along line X-X and FIG. 3 depicts a cross-sectional view of the structure 100 shown in FIG. 4 taken along line Y-Y.

The structure 100 illustrated in FIGS. 2-3 includes an array of nanosheet transistors formed on a substrate 102 in accordance with known techniques. As illustrated, the array of nanosheet transistors includes nanosheet stacks 104. Each nanosheet stack 104 includes a plurality of silicon channels 106 surrounded by a single gate 108, collectively referred to as the gates 108. For purposes of orientation, the substrate 102 is herein referred to as being on a “backside” of the structure 100 and the array of nanosheet transistors are herein referred to as being on a “frontside” of the structure 100. Further, certain features may be described herein as having a relative position with respect to the frontside or backside of the structure 100.

The substrate 102 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 102 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon. Additionally, both the etch stop layer 110 and the base substrate 112 are sacrificial and will not remain in the final structure. As such, thickness of the top semiconductor layer 114, and similarly the position of the etch stop layer 110, approximately denote a relative position of subsequently formed backside features, such as, backside wiring layers or a backside power delivery network.

The structure 100 further includes shallow trench isolation regions (hereinafter “STI regions”) which extend partially into the substrate 102 below the array of nanosheet transistors. In general, the STI regions may each include an isolation liner 116 and an isolation fill 118. For example, the isolation liner 116 is SiN, SiON, or SiOCN, and the isolation fill 118 is silicon oxide (SiO) or silicon nitride (SiN).

The structure 100 further includes source drain regions 120 generally arranged between adjacent nanosheet stacks 104, as illustrated.

The source drain regions 120 are formed according to known techniques. Specifically, the source drain regions 120 are disposed between adjacent nanosheet stacks 104 in direct contact with exposed ends of the silicon channels 106. More specifically, the source drain regions 120 may be epitaxially grown from the exposed ends of the silicon channels 106 according to known techniques.

The structure 100 further includes inner spacers 126 and gate spacers 128.

The inner spacers 126 are disposed between alternate channels (106), and laterally separate the gates 108 from the source drain regions 120, as illustrated. The inner spacers 126 provide necessary electrical insulation between the gates 108 and the source drain regions 120.

The gate spacers 128 are added to define the channel length and the source drain regions, and ultimately electrically insulate the gates 108 from subsequently formed structures, such as, for example, source drain contact structures. The gate spacers 128 are critical for electrically insulating the gates 108 from the source drain regions 120 or subsequently formed contact structures. In at least one embodiment, the gate spacers 128 include silicon nitride, silicon boron nitride, silicon carbon nitride, silicon boron carbon nitride, or other known equivalents.

Finally, the structure 100 further includes a dielectric layer 130, a middle-of-line 132, a back-end-of-line 134, a carrier wafer 136.

The dielectric layer 130 is formed on top of the structure 100 and substantially surrounds the source drain regions 120 according to known techniques. The dielectric layer 130 is composed of any suitable interlayer dielectric material, such as, for example, oxides such as silicon oxide (SiOₓ), nitrides such as silicon nitride (SiₓN_{y}), and/or low-κ materials such as SiCOH or SiBCN. In another embodiment, is composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, a self-planarizing material such as a spin-on glass (SOG) or a spin-on low-k dielectric material such as SiLK™ can be used to form the dielectric layer 130. Using a self-planarizing dielectric material as the dielectric layer 130 can avoid the need to perform a subsequent planarizing step. After formation, top surfaces of the dielectric layer 130 are typically made flush, or substantially flush, with top surfaces of the gates 108 and the gate spacers 128 by chemical mechanical polishing techniques.

The middle-of-line 132 includes source drain contacts 138 and gate contacts (not shown) which may be generally referred to as middle-of-line contacts. The source drain contacts 138 and the gate contacts are formed according to known techniques. The back-end-of-line 134 may include vias and metal lines which may be generally referred to as back-end-of-line interconnects. The vias and the metal lines are formed according to known techniques. Finally, the carrier wafer 136 is secured to a top of the structure 100 according to an embodiment of the invention. The carrier wafer 136 is attached, or removably secured, to the back-end-of-line 134. In general, and not depicted, the carrier wafer 136 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 136 according to known techniques.

Although only a limited number of components, devices, or structures are shown, embodiments of the present invention shall not be limited by any quantity otherwise illustrated or discussed herein.

Referring now to FIGS. 4 and 5, the structure 100 is shown after flipping the assembly and recessing the substrate 102 according to an embodiment of the invention. FIG. 4 depicts a cross-sectional view of the structure 100 shown in FIG. 5 taken along line X-X and FIG. 5 depicts a cross-sectional view of the structure 100 shown in FIG. 4 taken along line Y-Y.

First, the structure 100 is flipped 180 degrees to prepare for backside processing. In general, backside processing includes fabrication or processing of the structure 100 opposite the active device and wiring layers. Next, the substrate 102 is recessed according to known techniques. Specifically, the base substrate 112 is recessed or completely removed to expose the etch stop layer 110, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

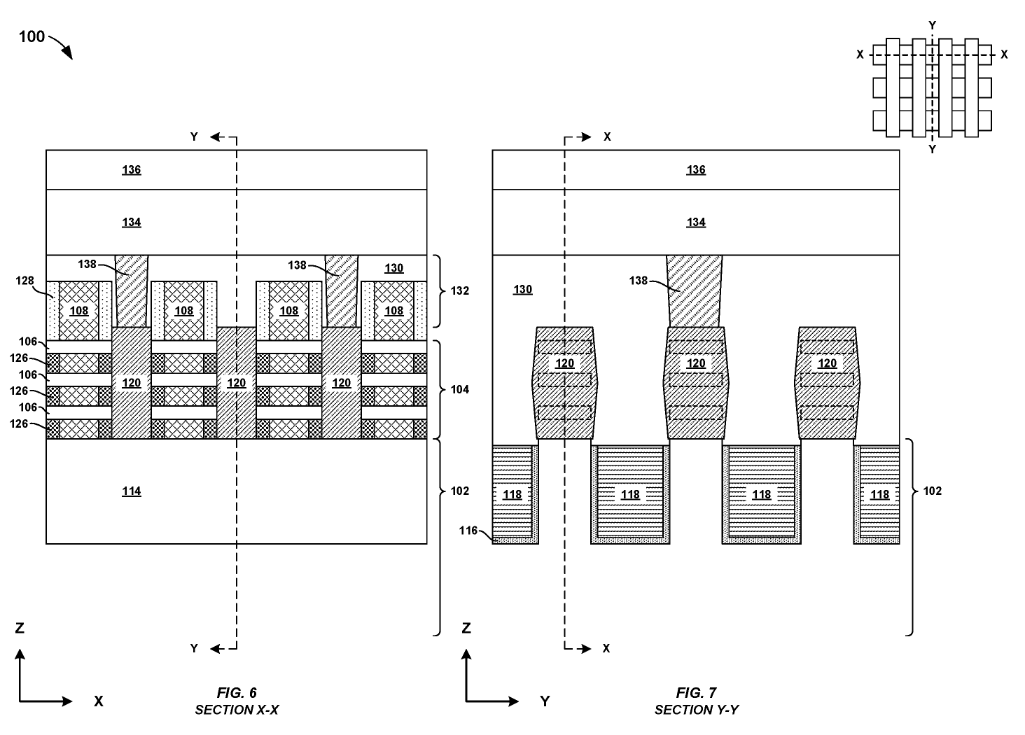

Referring now to FIGS. 6 and 7, the structure 100 is shown after removing and recessing remaining portions of the substrate 102 according to an embodiment of the invention. FIG. 6 depicts a cross-sectional view of the structure 100 shown in FIG. 7 taken along line X-X and FIG. 7 depicts a cross-sectional view of the structure 100 shown in FIG. 6 taken along line Y-Y.

First, the etch stop layer 110 is selectively removed and the top semiconductor layer 114 is exposed according to known techniques. Specifically, the etch stop layer 110 is removed selective to the top semiconductor layer 114. In the present embodiment, removal of the etch stop layer 110 exposed bottommost surfaces of both the STI regions and the top semiconductor layer 114, as illustrated. In other embodiments, the STI regions do not extend a full depth of the top semiconductor layer 114 and additional recessing techniques are applied to recess the top semiconductor layer 114 flush or substantially flush with the STI regions.

Next, the top semiconductor layer 114 is further recessed and removed from portions of the structure 100 according to known techniques. Specifically, the top semiconductor layer 114 is removed from all portions of the structure 100 except where N-well or P-well regions. For example, the top semiconductor layer 114 is entirely removed from portions of the structure 100 illustrated in FIG. 7, but not portions of the structure 100 illustrated in FIG. 6. According to the disclosed embodiments, N-well or P-well regions are selectively arranged and provide a substrate connection for passive device. Additionally, the remaining portions of the top semiconductor layer 114, otherwise known as N-well or P-well regions, remain below and directly contact bottoms of the gate 108 and the source drain regions 120, as best illustrated in FIG. 6.

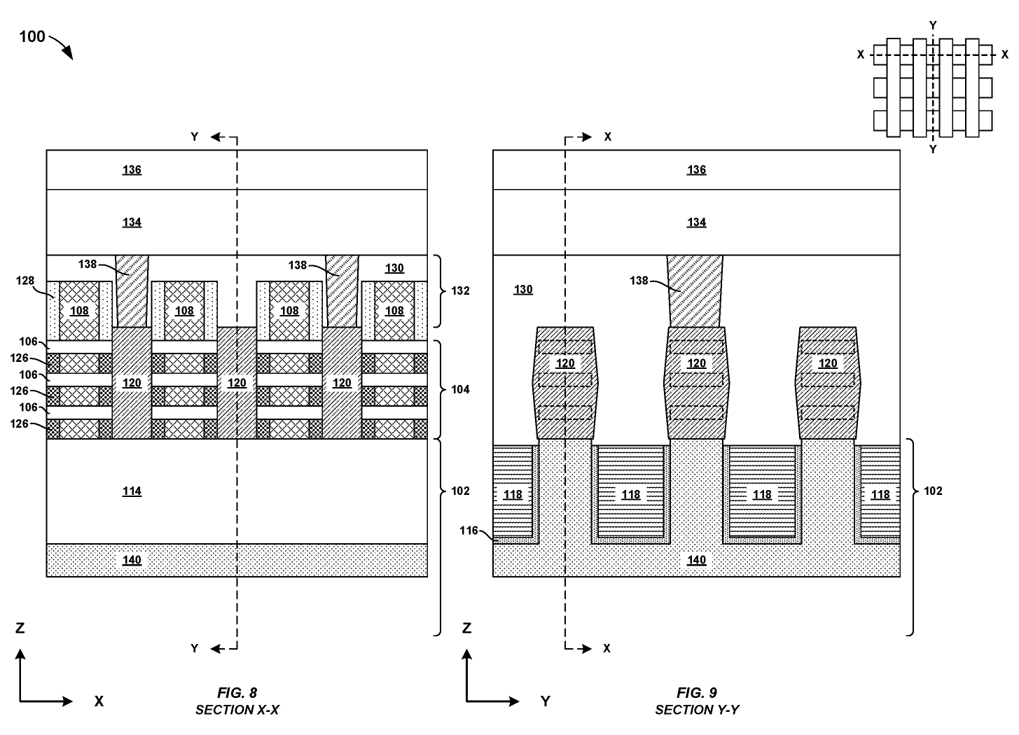

Referring now to FIGS. 8 and 9, the structure 100 is shown after forming backside dielectric layer 140 according to an embodiment of the invention. FIG. 8 depicts a cross-sectional view of the structure 100 shown in FIG. 9 taken along line X-X and FIG. 9 depicts a cross-sectional view of the structure 100 shown in FIG. 8 taken along line Y-Y.

The backside dielectric layer 140 is deposited according to known techniques. Specifically, a backside dielectric material is blanket deposited across the structure 100. The backside dielectric layer 140 completely covers remaining portions of the top semiconductor layer 114 and the STI regions. After deposition, known chemical mechanical polishing may be used to remove excess portions of the backside dielectric material from bottom surfaces of the structure 100. According to the disclosed embodiments, chemical mechanical polishing is used to planarize the surface of the backside dielectric layer 140 without exposing the STI regions, as illustrated.

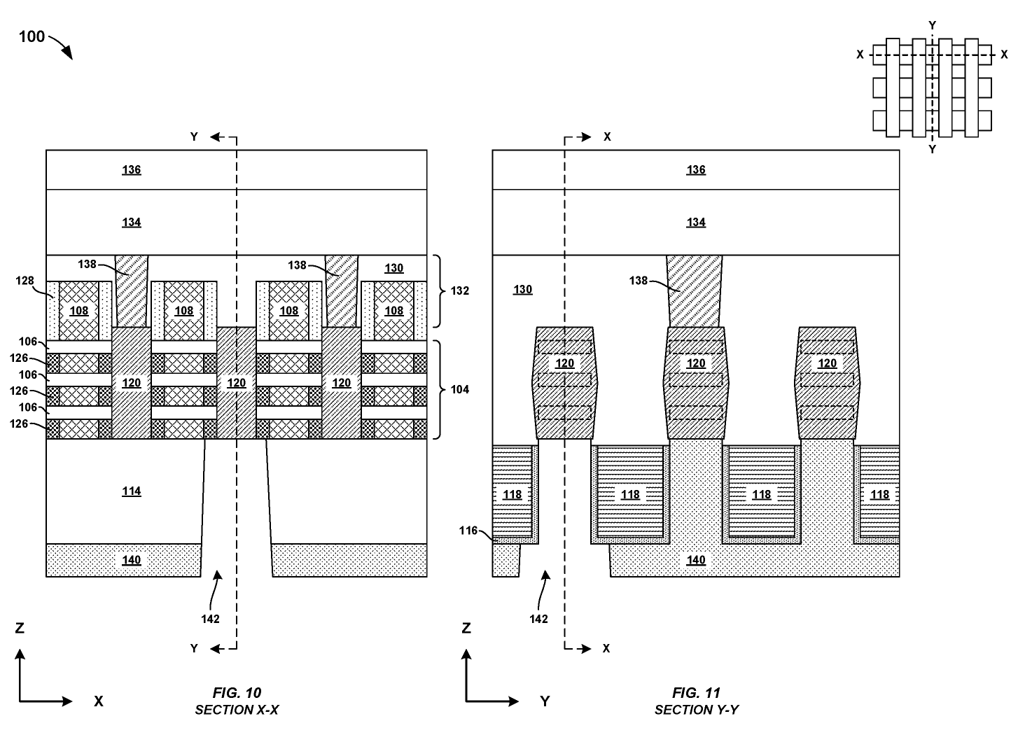

Referring now to FIGS. 10 and 11, the structure 100 is shown after forming backside contact trenches 142 according to an embodiment of the invention. FIG. 10 depicts a cross-sectional view of the structure 100 shown in FIG. 11 taken along line X-X and FIG. 11 depicts a cross-sectional view of the structure 100 shown in FIG. 10 taken along line Y-Y.

First, a mask (not shown) is deposited and subsequently patterned to expose certain portions of the structure 100 according to known techniques. The mask can be an organic planarization layer (OPL) or a layer of material that is capable of being planarized or etched by known techniques. In an embodiment, for example, the mask can be an amorphous carbon layer able to withstand subsequent processing temperatures. The mask can preferably have a thickness sufficient to cover existing structures. After depositing the mask, a dry etching technique is applied to pattern or recess the mask according to known techniques. The mask is patterned consistent with a size and a location of subsequently formed backside contact structures. For example, after patterning the mask, portions of the structure 100 in contact regions are exposed, as illustrated.

Next, exposed portions of the backside dielectric layer 140 and underlying portions of the top semiconductor layer 114 are then selectively removed to form the backside contact trenches 142 according to known techniques. Specifically, exposed portions of the backside dielectric layer 140 and underlying portions of the top semiconductor layer 114 are removed using known etching techniques suitable to remove silicon-based dielectric materials selective to the mask, the STI regions, the inner spacers 126, and the source drain regions 120, as illustrated. In an embodiment, the exposed portions of the backside dielectric layer 140 and underlying portions of the top semiconductor layer 114 are removed using an anisotropic etch such as, for example, reactive ion etching (RIE). After removing the exposed portions of the backside dielectric layer 140 and underlying portions of the top semiconductor layer 114, portions of the STI regions, the inner spacers 126, and the source drain regions 120 are exposed within the backside contact trenches 142, as illustrated. Significant to the embodiments disclosed herein, etching must continue until at least bottommost surfaces of the source drain regions 120 are exposed. In such cases, some or all of the backside dielectric layer 140 in the contact regions is completely removed from between adjacent STI regions, as best illustrated in FIG. 11.

Specific to the disclosed embodiments, it is noted that the backside contact trenches 142 extend, or pass through, the top semiconductor layer 114. Said differently, sidewalls of the top semiconductor layer 114 are exposed within the backside contact trenches 142, as best illustrated in FIG. 10.

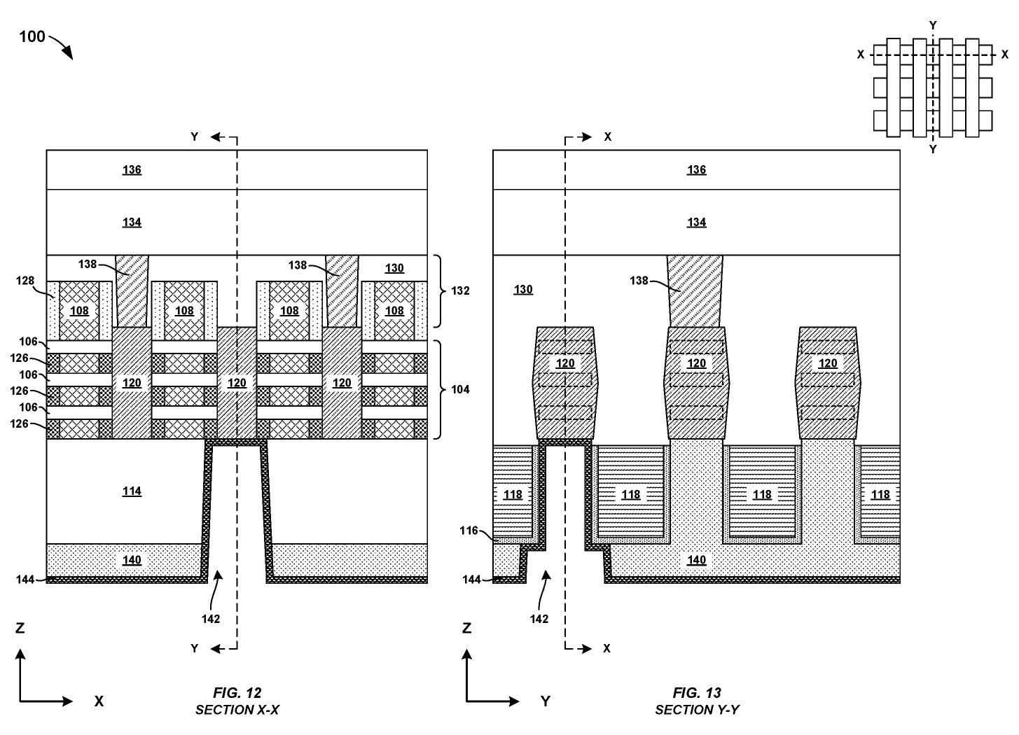

Referring now to FIGS. 12 and 13, the structure 100 is shown after forming a dielectric liner 144 according to an embodiment of the invention. FIG. 12 depicts a cross-sectional view of the structure 100 shown in FIG. 13 taken along line X-X and FIG. 13 depicts a cross-sectional view of the structure 100 shown in FIG. 12 taken along line Y-Y.

The dielectric liner 144 is formed across the backside of the structure 100 according to known techniques. Specifically, a liner material is conformally deposited across exposed surfaces on the backside of the structure 100 including directly on exposed surfaces on the backside of the structure 100 and within the backside contact trenches 142, as illustrated. In some embodiments, for example, the dielectric liner 144 may be composed of other low-k materials, such as, for example, SiN, SiBCN, SiOCN, SiOC, or other combinations thereof. According to embodiments of the present invention, the dielectric liner 144 provide etch selectivity during backside processing. More specifically, the dielectric liner 144 must be made from a material which may be removed selective to the backside dielectric layer 140, as described below.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

According to the disclose embodiments, the dielectric liner 144 shall be formed of a sufficient thickness to ensure subsequently formed isolation features adequality separate the gates 108 from subsequently formed backside contact structures, as described in more detail below. According to an embodiment, the dielectric liner 144 has a conformal thickness of at least 2 nm to ensure a continuous film. Additionally, thickness of the dielectric liner 144 should be limited to prevent unwarranted or unintended increases in contact resistance.

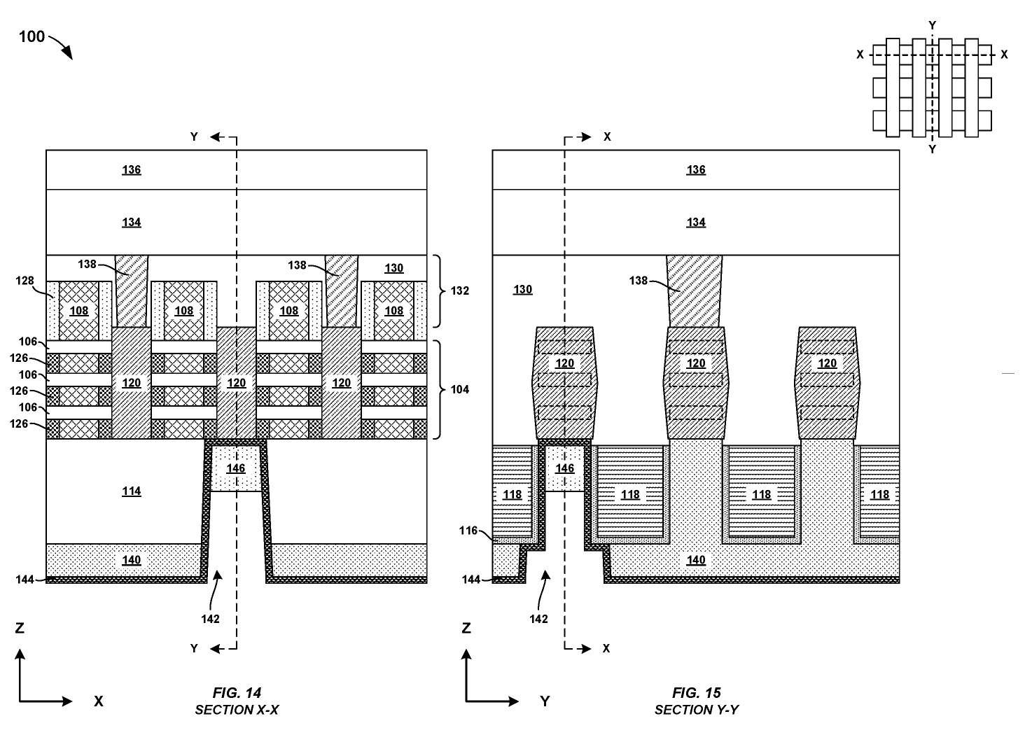

Referring now to FIGS. 14 and 15, the structure 100 is shown after forming a mask 146 according to an embodiment of the invention. FIG. 14 depicts a cross-sectional view of the structure 100 shown in FIG. 15 taken along line X-X and FIG. 15 depicts a cross-sectional view of the structure 100 shown in FIG. 14 taken along line Y-Y.

The mask 146 is formed according to known techniques. Specifically, mask material is deposited and subsequently patterned to expose certain portions of the structure 100 according to known techniques. The mask 146 can be an organic planarization layer (OPL) or a layer of material that is capable of being planarized or etched by known techniques. In an embodiment, for example, the mask 146 can be an amorphous carbon layer able to withstand subsequent processing temperatures. The mask 146 can preferably have a thickness sufficient to cover existing structures. After depositing the mask 146, a dry etching technique is applied to pattern or recess the mask 146 according to known techniques. The mask 146 is patterned, or recessed, such that portions of the mask 146 remain within the backside contact trenches 142, as illustrated. For example, after patterning the mask 146, substantially all backside surfaces of the structure 100 are exposed, except for topmost portions of the backside contact trenches 142, as illustrated. According to the disclosed embodiments, the mask 146 is patterned selective to the dielectric liner 144, as illustrated.

In all cases, portions of the mask 146 must remain within the backside contact trenches 142. Said differently, portions of the mask 146 shall only be removed from a portion of the backside contact trenches 142, as illustrated. How much of the mask 146 is removed depends on how much of the dielectric liner 144 shall be protected and preserved in the final structure. According to an embodiment, the remaining portions of the mask 146 fill at least approximately 10 percent of a depth of each the backside contact trenches 142. According to an alternative embodiment, the remaining portions of the mask 146 fill at most approximately 90 percent of a depth of each the backside contact trenches 142. Therefore, embodiments of the present disclosure explicitly contemplate the remaining portions of the mask 146 filling approximately 10 percent to approximately 90 percent of a depth of each the backside contact trenches 142.

Furthermore, according to embodiments of the present invention, the gates 108 extend down into the top semiconductor layer 114. In such embodiments, it is critical the mask 146 is not recessed to a level at or above bottom surfaces of the gates 108. Doing so ensures subsequently formed isolation features (ie a dielectric liner) adequality separate the gates 108 from subsequently formed backside contact structures, as described in more detail below.

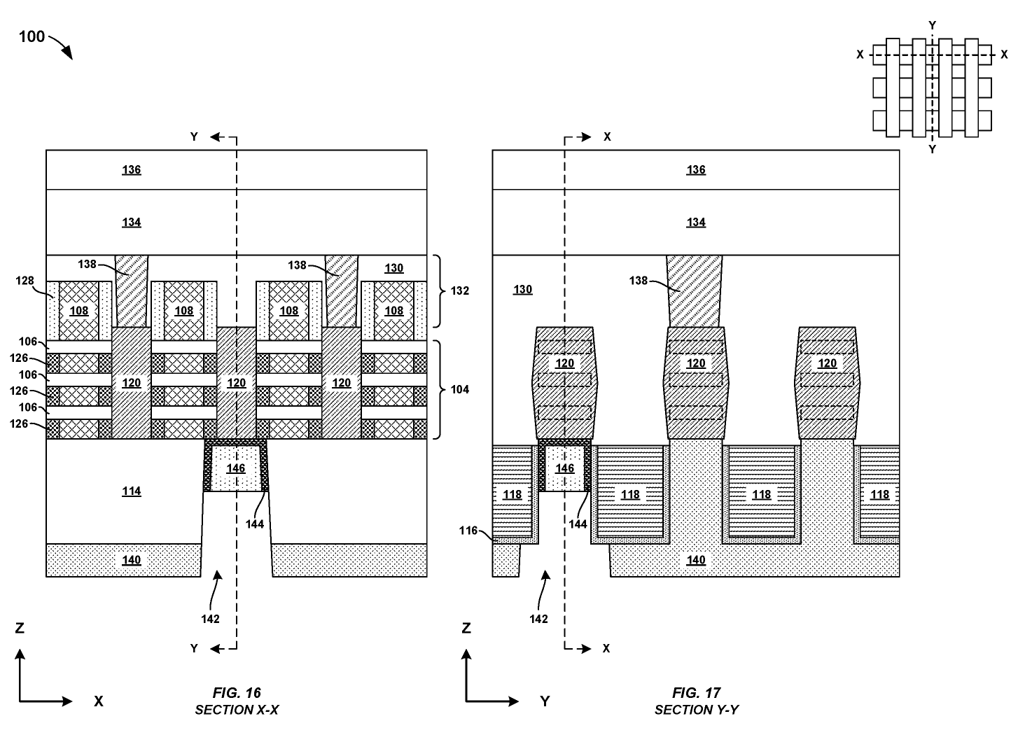

Referring now to FIGS. 16 and 17, the structure 100 is shown after removing portions of the dielectric liner 144 according to an embodiment of the invention. FIG. 16 depicts a cross-sectional view of the structure 100 shown in FIG. 17 taken along line X-X and FIG. 17 depicts a cross-sectional view of the structure 100 shown in FIG. 16 taken along line Y-Y.

Exposed portions of the dielectric liner 144 are selectively remove according to known techniques. Specifically, exposed portions of the dielectric liner 144 are removed using known etching techniques suitable to remove silicon-based materials selective to the mask 146. In an embodiment, the exposed portions of the dielectric liner 144 are removed using an anisotropic etch such as, for example, reactive ion etching. After removing the exposed portions of the dielectric liner 144, sidewalls of the top semiconductor layer 114 become exposed, as best illustrated in FIG. 16. Remaining portions of the dielectric liner 144 are protected by the mask 146.

In all cases, portions of the dielectric liner 144 must remain within the backside contact trenches 142. Said differently, portions of the dielectric liner 144 shall only be removed from a portion of the backside contact trenches 142, as illustrated. How much of the dielectric liner 144 is removed depends on the formation of the mask 146.

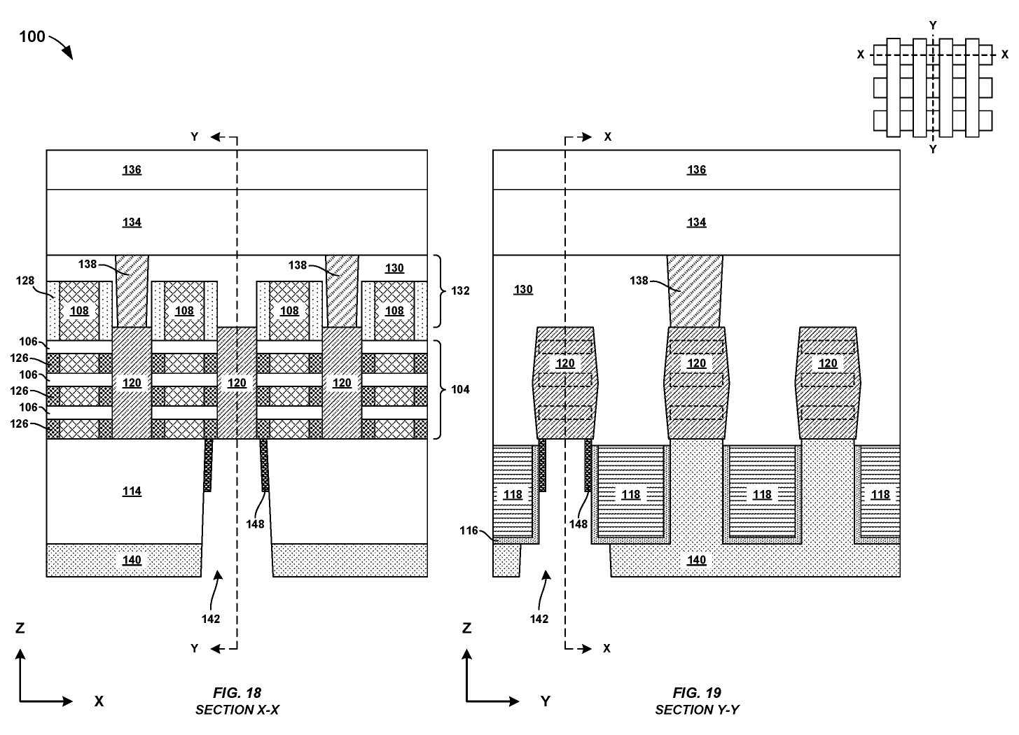

Referring now to FIGS. 18 and 19, the structure 100 is shown after removing additional portions of the dielectric liner 144 to form sidewall spacers 148 according to an embodiment of the invention. FIG. 18 depicts a cross-sectional view of the structure 100 shown in FIG. 19 taken along line X-X and FIG. 19 depicts a cross-sectional view of the structure 100 shown in FIG. 18 taken along line Y-Y.

First, the mask 146 is removed according to known techniques. In an embodiment, the mask 146 is removed using techniques, such as, for example, ashing.

Next, additional portions of the dielectric liner 144 are removed according to known techniques. Specifically, additional portions of the dielectric liner 144 are substantially removed from horizontal surfaces to form the sidewall spacers 148. In doing so, portions of the of the dielectric liner 144, now the sidewall spacers 148, remain on sidewalls of the backside contact trenches 142, as illustrated. Known directional etching techniques, for example reactive ion etching, may be used to remove remaining portions of the dielectric liner 144 from horizontal surfaces. Doing so will remove portions of the dielectric liner material from tops of the backside contact trenches 142 thereby exposing bottom surfaces of some of the source drain regions 120, as illustrated.

In all cases, the sidewall spacers 148 remain along sidewall portions of the backside contact trenches 142, as illustrated. Said differently, portions of the dielectric liner 144 shall only be removed from substantially horizontal surfaces within the backside contact trenches 142, as illustrated. According to an embodiment, the sidewall spacers 148 cover at least approximately 10 percent of a height of the sidewalls of each the backside contact trenches 142. According to an alternative embodiment, the sidewall spacers 148 cover at least approximately 90 percent of the height of the sidewalls of each the backside contact trenches 142. Therefore, embodiments of the present disclosure explicitly contemplate the sidewall spacers 148 cover approximately 10 percent to approximately 90 percent of the height of the sidewalls of each the backside contact trenches 142.

As described above, the gates 108 extend down into the top semiconductor layer 114 in some embodiments. In such embodiments, it is critical that bottommost surfaces of the dielectric liner 144 are below bottommost surfaces of the gates 108 to ensure adequate isolation between the gates 108 and subsequently formed backside contact structures. For example, isolation between the gates 108 and subsequently formed backside contact structures is adequate if the dielectric liner 144 are below bottommost surfaces of the gates 108 by at least 5 nm.

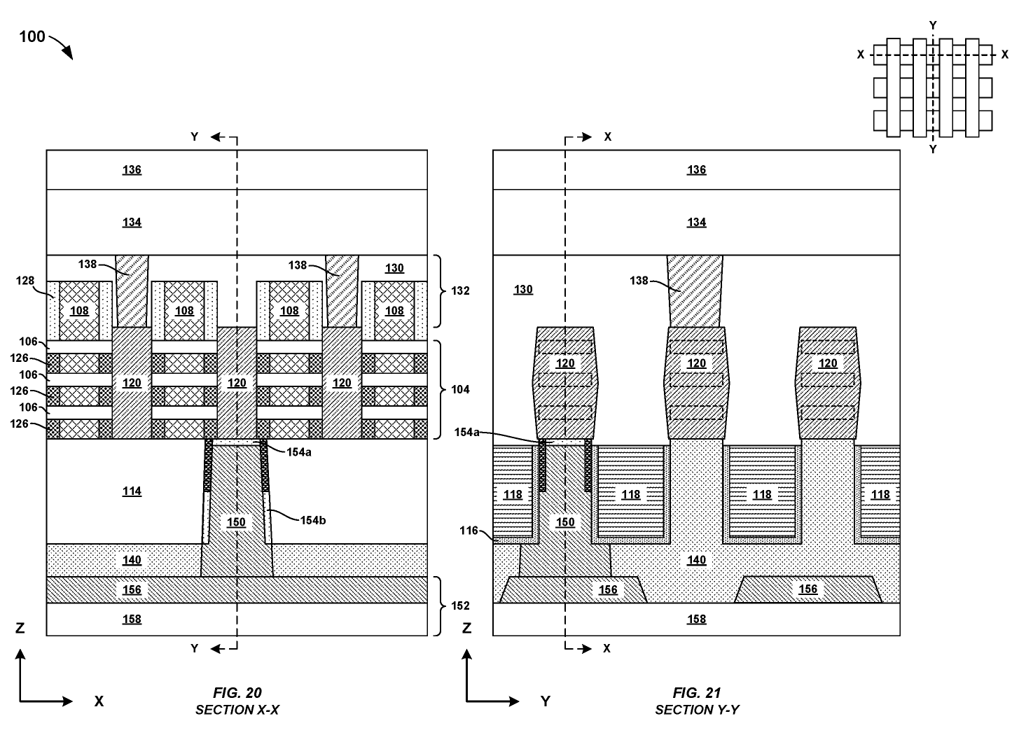

Referring now to FIGS. 20 and 21, the structure 100 is shown after forming backside contact structures 150 and backside wiring layers 152 according to an embodiment of the invention. FIG. 20 depicts a cross-sectional view of the structure 100 shown in FIG. 21 taken along line X-X and FIG. 21 depicts a cross-sectional view of the structure 100 shown in FIG. 20 taken along line Y-Y.

The backside contact trenches 142 are filled with a conductive material to form the backside contact structures 150 according to known techniques. The backside contact structures 150 may include any suitable conductive material, such as, for example, copper, ruthenium, aluminum, tungsten, cobalt, or alloys thereof. In some embodiments, first metal silicide regions 154a are formed at the top of the backside contact trenches 142 prior to filling them with the conductive material, and according to known techniques. In doing so, second metal silicide regions 154b may also form along sidewalls of the top semiconductor layer 114 exposed within the backside contact trenches 142.

After deposition, excess conductive material can be polished using known techniques until bottommost surfaces of the backside contact structures 150 are flush, or substantially flush, with bottommost surfaces of the backside dielectric layer 140, as illustrated. After polishing, bottommost surfaces of the backside contact structures 150 are substantially flat. It is noted, the backside contact structures 150 may include, for example, backside source drain contacts, as illustrated, as well as backside gate contacts (not shown).

After forming the backside contact structures 150, the backside wiring layers 152 are subsequently formed according to known techniques. The backside wiring layers 152 typically include at least backside power rails 156 and a backside power delivery network 158.

According to the embodiment illustrated in FIGS. 20 and 21, the transistor structures represented by the structure 100 have some distinctive notable features. For instance, the structure 100 includes backside contact structures 150 with a sidewall spacer, specifically the dielectric liner 144. The dielectric liner 144 creates additional distance between the gates 108 and the backside contact structures 150 without requiring the complete removal of any backside silicon layer, for example, the top semiconductor layer 114. The additional distance between the gates 108 and the backside contact structures 150 helps prevent the first metal silicide regions 154a from diffusing into the top semiconductor layer 114 and shorting to the gates 108. Moreover, because the dielectric liner 144 is covers less than the entire height of the sidewalls of each the backside contact trenches 142, bottom portions of the backside contact structures 150 remain in direct contact with the top semiconductor layer 114.

Of note, the structure 100 and associated method described herein eliminate the need for alternative, albeit more complicated, solutions. One of the alternative, more complicated solutions, may involve completely removing all backside substrate materials and replacing with backside dielectric materials; however, doing so requires additional processes and/or structures to limit or prevent damage to the source drain regions during removal. For example, additional isolation layers or structures may otherwise be required physically separate, and protect, the source drain regions, specifically N-dope regions, during removal of any backside substrate materials

With continued reference to FIGS. 20 and 21, and according to an embodiment, the structure 100 includes a backside contact structure, top semiconductor layer adjacent to, and in electrical contact with, a bottom portion of the backside contact structure, and sidewall spacers between and physically separating a top portion of the backside contact structure from the top semiconductor layer.

With continued reference to FIGS. 20 and 21, and according to an embodiment, the structure further includes a backside dielectric layer below the top semiconductor layer, wherein the backside dielectric layer physically separates the top semiconductor layer from a backside power rail.

With continued reference to FIGS. 20 and 21, and according to an embodiment, the sidewall spacers directly contact inners spacers present on opposite sides of a source drain region.

With continued reference to FIGS. 20 and 21, and according to an embodiment, a bottommost surface of the backside contact structure is substantially flat and directly contacts a backside power rail.

With continued reference to FIGS. 20 and 21, and according to an embodiment, wherein the backside contact structure is self-aligned to adjacent shallow trench isolation regions.

With continued reference to FIGS. 20 and 21, and according to an embodiment, the sidewall spacers are between and physically separate the top portion of the backside contact structure from adjacent shallow trench isolation regions.

With continued reference to FIGS. 20 and 21, and according to an embodiment, the top semiconductor layer directly contacts a bottom portion of a gate structure.

With continued reference to FIGS. 20 and 21, and according to an embodiment, the structure 100 includes a backside contact structure, top semiconductor layer adjacent to, and in electrical contact with, a bottom portion of the backside contact structure, sidewall spacers between and physically separating a top portion of the backside contact structure from the top semiconductor layer, and a first silicide region arranged at a top of the backside contact structure.

With continued reference to FIGS. 20 and 21, and according to an embodiment, the structure 100 includes a backside contact structure, a top semiconductor layer adjacent to, and in electrical contact with, a bottom portion of the backside contact structure, sidewall spacers between and physically separating a top portion of the backside contact structure from the top semiconductor layer, a first silicide region between and direct contacting the backside contact structure and a source drain region, and a second silicide region between and direct contacting the backside contact structure the top semiconductor layer.

Various examples may possibly be described by one or more of the following features in the following numbered clauses:

Clause 1: A nanosheet semiconductor structure including a backside contact structure, top semiconductor layer adjacent to, and in electrical contact with, a bottom portion of the backside contact structure, and sidewall spacers between and physically separating a top portion of the backside contact structure from the top semiconductor layer.

Clause 2: The semiconductor structure according to clause 1, further including a backside dielectric layer below the top semiconductor layer, wherein the backside dielectric layer physically separates the top semiconductor layer from a backside power rail.

Clause 3: The semiconductor structure according to clauses 1 and 2, where the sidewall spacers directly contact inner spacers present on opposite sides of a source drain region.

Clause 4: The semiconductor structure according to clauses 1, 2, and 3, where a bottommost surface of the backside contact structure is substantially flat and directly contacts a backside power rail.

Clause 5: The semiconductor structure according to clauses 1, 2, 3, and 4, where the backside contact structure is self-aligned to adjacent shallow trench isolation regions.

Clause 6: The semiconductor structure according to clauses 1, 2, 3, 4, and 5, where the sidewall spacers are between and physically separate the top portion of the backside contact structure from adjacent shallow trench isolation regions.

Clause 7: The semiconductor structure according to clauses 1, 2, 3, 4, 5, and 6, where the top semiconductor layer directly contacts a bottom portion of a gate structure.

Clause 8: A nanosheet semiconductor structure including a backside contact structure, top semiconductor layer adjacent to, and in electrical contact with, a bottom portion of the backside contact structure, sidewall spacers between and physically separating a top portion of the backside contact structure from the top semiconductor layer, and a first silicide region arranged at a top of the backside contact structure.

Clause 9: The semiconductor structure according to clause 8, further including a backside dielectric layer below the top semiconductor layer, wherein the backside dielectric layer physically separates the top semiconductor layer from a backside power rail.

Clause 10: The semiconductor structure according to clauses 8 and 9, where the sidewall spacers directly contact inner spacers present on opposite sides of a source drain region.

Clause 11: The semiconductor structure according to clauses 8, 9, and 10, where a bottommost surface of the backside contact structure is substantially flat and directly contacts a backside power rail.

Clause 12: The semiconductor structure according to clauses 8, 9, 10, and 11, where the backside contact structure is self-aligned to adjacent shallow trench isolation regions.

Clause 13: The semiconductor structure according to clauses 8, 9, 10, 11, and 12, where the sidewall spacers are between and physically separate the top portion of the backside contact structure from adjacent shallow trench isolation regions.

Clause 14: The semiconductor structure according to clauses 8, 9, 10, 11, 12, and 13, where the top semiconductor layer directly contacts a bottom portion of a gate structure.

Clause 15: A nanosheet semiconductor structure including a backside contact structure, a top semiconductor layer adjacent to, and in electrical contact with, a bottom portion of the backside contact structure, sidewall spacers between and physically separating a top portion of the backside contact structure from the top semiconductor layer, a first silicide region between and direct contacting the backside contact structure and a source drain region, and a second silicide region between and direct contacting the backside contact structure the top semiconductor layer.

Clause 16: The semiconductor structure according to clause 15, further including a backside dielectric layer below the top semiconductor layer, where the backside dielectric layer physically separates the top semiconductor layer from a backside power rail.

Clause 17: The semiconductor structure according to clauses 15 and 16, where the sidewall spacers directly contact inner spacers present on opposite sides of the source drain region.

Clause 18: The semiconductor structure according to clauses 15, 16, and 17, where a bottommost surface of the backside contact structure is substantially flat and directly contacts a backside power rail.

Clause 19: The semiconductor structure according to clauses 15, 16, 17, and 18, where the sidewall spacers are between and physically separate the top portion of the backside contact structure from adjacent shallow trench isolation regions.

Clause 20: The semiconductor structure according to clauses 15, 16, 17, 18, and 19, where the top semiconductor layer directly contacts a bottom portion of a gate structure.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A nanosheet semiconductor structure comprising:
a backside contact structure;
top semiconductor layer adjacent to, and in electrical contact with, a bottom portion of the backside contact structure; and
sidewall spacers between and physically separating a top portion of the backside contact structure from the top semiconductor layer.

2. The nanosheet semiconductor structure according to claim 1, further comprising:
a backside dielectric layer below the top semiconductor layer, wherein the backside dielectric layer physically separates the top semiconductor layer from a backside power rail.

3. The nanosheet semiconductor structure according to claim 1, wherein the sidewall spacers directly contact inner spacers present on opposite sides of a source drain region.

4. The nanosheet semiconductor structure according to claim 1, wherein a bottommost surface of the backside contact structure is substantially flat and directly contacts a backside power rail.

5. The nanosheet semiconductor structure according to claim 1, wherein the backside contact structure is self-aligned to adjacent shallow trench isolation regions.

6. The nanosheet semiconductor structure according to claim 1, wherein the sidewall spacers are between and physically separate the top portion of the backside contact structure from adjacent shallow trench isolation regions.

7. The nanosheet semiconductor structure according to claim 1, wherein the top semiconductor layer directly contacts a bottom portion of a gate structure.

8. A nanosheet semiconductor structure comprising:
a backside contact structure;
top semiconductor layer adjacent to, and in electrical contact with, a bottom portion of the backside contact structure;
sidewall spacers between and physically separating a top portion of the backside contact structure from the top semiconductor layer; and
a first silicide region arranged at a top of the backside contact structure.

9. The nanosheet semiconductor structure according to claim 8, further comprising:
a backside dielectric layer below the top semiconductor layer, wherein the backside dielectric layer physically separates the top semiconductor layer from a backside power rail.

10. The nanosheet semiconductor structure according to claim 8, wherein the sidewall spacers directly contact inner spacers present on opposite sides of a source drain region.

11. The nanosheet semiconductor structure according to claim 8, wherein a bottommost surface of the backside contact structure is substantially flat and directly contacts a backside power rail.

12. The nanosheet semiconductor structure according to claim 8, wherein the backside contact structure is self-aligned to adjacent shallow trench isolation regions.

13. The nanosheet semiconductor structure according to claim 8, wherein the sidewall spacers are between and physically separate the top portion of the backside contact structure from adjacent shallow trench isolation regions.

14. The nanosheet semiconductor structure according to claim 8, wherein the top semiconductor layer directly contacts a bottom portion of a gate structure.

15. A nanosheet semiconductor structure comprising:
a backside contact structure;
a top semiconductor layer adjacent to, and in electrical contact with, a bottom portion of the backside contact structure;
sidewall spacers between and physically separating a top portion of the backside contact structure from the top semiconductor layer;
a first silicide region between and direct contacting the backside contact structure and a source drain region; and
a second silicide region between and direct contacting the backside contact structure the top semiconductor layer.

16. The nanosheet semiconductor structure according to claim 15, further comprising:
a backside dielectric layer below the top semiconductor layer, wherein the backside dielectric layer physically separates the top semiconductor layer from a backside power rail.

17. The nanosheet semiconductor structure according to claim 15, wherein the sidewall spacers directly contact inner spacers present on opposite sides of the source drain region.

18. The nanosheet semiconductor structure according to claim 15, wherein a bottommost surface of the backside contact structure is substantially flat and directly contacts a backside power rail.

19. The nanosheet semiconductor structure according to claim 15, wherein the sidewall spacers are between and physically separate the top portion of the backside contact structure from adjacent shallow trench isolation regions.

20. The nanosheet semiconductor structure according to claim 15, wherein the top semiconductor layer directly contacts a bottom portion of a gate structure.
